(19) United States
(12) Patent Application Publication
(10) Pub. No.: US 2026/0372191 A1
(43) Pub. Date: Nov. 19, 2026

(54) INTEGRATED CIRCUIT PACKAGE AND METHOD

(71) Applicant: Taiwan Semiconductor Manufacturing Co., Ltd., Hsinchu (TW)

(72) Inventors: An-Jhih Su, Taoyuan (TW); Meng-Tsan Lee, Hsinchu (TW); Chun-Yi Liu, Hsinchu (TW); Shih-Wei Chen, Hsinchu (TW); Tai-You Liu, Hsinchu (TW); Po-Chang Shih, Taichung (TW); Der-Chyang Yeh, Hsinchu (TW)

(21) Appl. No.: 19/751,780

(22) Filed: Jul. 23, 2026

Related U.S. Application Data
(63) Continuation of application No. 19/047,976, filed on Feb. 7, 2025.
(60) Provisional application No. 63/699,654, filed on Sep. 26, 2024.

(51) Int. Cl. H10W 90/00; H10B 80/00; H10D 80/30; H10W 70/00; H10W 70/05; H10W 70/60; H10W 70/65; H10W 72/00; H10W 72/29; H10W 72/90; H10W 74/10; H10W 74/15

(52) U.S. Cl. CPC H10W 90/00; H10B 80/00; H10D 80/30; H10W 70/05; H10W 70/099; H10W 70/611; H10W 70/65; H10W 74/117; H10W 90/401; H10W 72/01361; H10W 72/29; H10W 72/823; H10W 72/923; H10W 72/952; H10W 74/15; H10W 90/724; H10W 90/734

(57) ABSTRACT

An integrated circuit package and the method of forming are provided. The integrated circuit package may include a first redistribution structure, a first bridge die over the first redistribution structure, a first encapsulant around the first bridge die, a second redistribution structure over the first bridge die and the first encapsulant, a first logic die, a second logic die, and a first input/output (I/O) die over the second redistribution structure, and a second encapsulant around the first logic die, the second logic die, and the first I/O die. The first I/O die may be between the first logic die and the second logic die in a top-down view. The first bridge die may electrically connect the first redistribution structure to the second redistribution structure. The first I/O die may electrically connect the first logic die to the second logic die.

### PRIORITY CLAIM AND CROSS-REFERENCE

This application is a continuation of U.S. patent application Ser. No. 19/047,976, filed Feb. 7, 2025, which application claims the benefit of U.S. Provisional Application No. 63/699,654, filed on Sep. 26, 2024, which applications are hereby incorporated herein by reference.

### BACKGROUND

As semiconductor technologies continue to evolve, integrated circuit dies are becoming increasingly smaller. Further, more functions are being integrated into the dies. Accordingly, the numbers of input/output (I/O) pads needed by dies has increased while the area available for the I/O pads has decreased. The density of the I/O pads has risen quickly over time, increasing the difficulty of die packaging.

In some packaging technologies, integrated circuit dies are singulated from wafers before they are packaged. An advantageous feature of this packaging technology is the possibility of forming fan-out packages, which allow the I/O pads on a die to be redistributed to a greater area. The number of I/O pads on the surfaces of the dies may thus be increased.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, and 1F illustrate cross-sectional views of various integrated circuit dies, in accordance with some embodiments.

FIGS. 2, 3, 4A, 4B, 5, 6, 7A, 7B, 8, 9, 10A, 10B, 11A, and 11B illustrate various views of intermediate steps during a process for forming an integrated circuit package, in accordance with some embodiments.

FIGS. 12, 13, and 14 illustrate various views of intermediate steps during a process for forming an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit package and methods of forming the same are provided. The package component may include a first wafer-scale redistribution structure, first integrated circuit dies bonded over the first wafer-scale redistribution structure, a second wafer-scale redistribution structure over first integrated circuit dies, and second integrated circuit dies bonded over the second wafer-scale redistribution structure. The first integrated circuit dies may be electrically connected to the first wafer-scale redistribution structure and the second wafer-scale redistribution structure. The second integrated circuit dies may be electrically connected to the second wafer-scale redistribution structure. Among the second integrated circuit dies located with a computing region over the second wafer-scale redistribution structure, some second integrated circuit dies may be logic dies, some second integrated circuit dies may be memory dies, and some second integrated circuit dies may be input/output (I/O) dies. The I/O dies within the computing region may facilitate communication among the logic dies and the memory dies within the computing region. The first integrated circuit dies may act as bridge dies and also facilitate communication among the logic dies and the memory dies within the computing region. As a result, communication among the logic dies and the memory dies within the computing region may be improved, thereby improving the performance of the integrated circuit package.

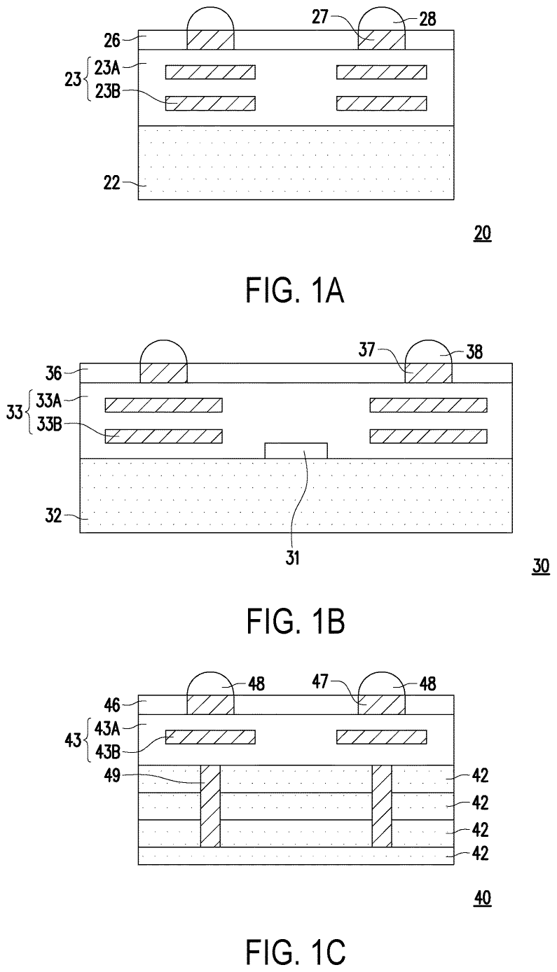

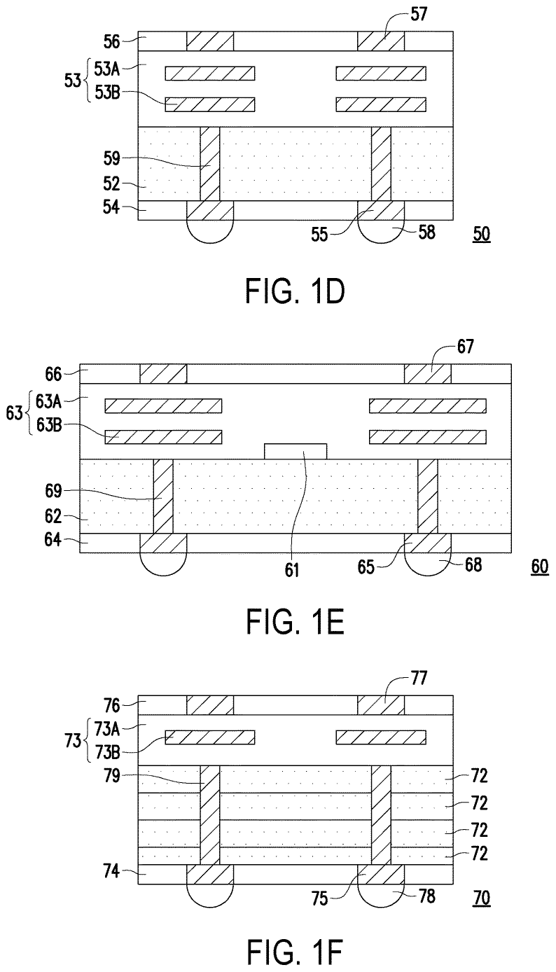

FIG. 1A illustrates a cross-sectional view of an integrated circuit die 20. The integrated circuit die 20 may be packaged in subsequent processing to form an integrated circuit package. The integrated circuit die 20 may be an input/output (I/O) die, or the like. The integrated circuit die 20 may include a semiconductor substrate 22. The semiconductor substrate 22 may comprise silicon, germanium, silicon-germanium, or the like. The semiconductor substrate 22 may have a front side (e.g., the side facing upwards in FIG. 1A), and a back side (e.g., the side facing downwards in FIG. 1A).

Devices (not shown) may be at the front side of the semiconductor substrate 22. The devices may be inactive devices, such as capacitors, resistors, or the like. The integrated circuit die 20 may be free of active devices, such as transistors or the like. The transistor may comprise a source region, a drain region, a channel region between the source region and the drain region, and a gate structure on the channel region. The integrated circuit die 20 may include an interconnect structure 23 over the front side of the semiconductor substrate 22, which may interconnect the devices to form an integrated circuit. The interconnect structure 23 may include dielectric layers 23A on the semiconductor substrate 22 and metallization patterns 23B in the dielectric layers 23A. The metallization patterns 23B may be electrically connected to the devices.

The integrated circuit die 20 may further include a passivation layer 26 on the interconnect structure 23 and conductive pads 27 in the passivation layer 26. The conductive pads 27 may be physically and electrically connected to the metallization patterns 23B. The passivation layer 26 may comprise silicon nitride, silicon oxide, polyimide, or the like. The conductive pads 27 may comprise copper, nickel, aluminum, the like, or combinations thereof. Conductive connectors 28 may be on the conductive pads 27. The conductive connectors 28 may be solder, such as lead-free solder, or the like.

FIG. 1B illustrates a cross-sectional view of an integrated circuit die 30. The integrated circuit die 30 may be packaged in subsequent processing to form an integrated circuit package. The integrated circuit die 30 may be a logic die, such as processing unit (CPU), graphics processing unit (GPU), system-on-a-chip (SoC), application processor (AP), microcontroller, or the like. The integrated circuit die 30 may include a semiconductor substrate 32. The semiconductor substrate 32 may comprise silicon, germanium, silicon-germanium, or the like. The semiconductor substrate 32 may have a front side (e.g., the side facing upwards in FIG. 1B), and a back side (e.g., the side facing downwards in FIG. 1B).

Devices 31 may be at the front side of the semiconductor substrate 32. The devices 31 may be active devices, such as transistors, or the like. The transistor may comprise a source region, a drain region, a channel region between the source region and the drain region, and a gate structure on the channel region. Other inactive devices (not shown), such as capacitors, resistors, or the like, may be also at the front side of the semiconductor substrate 32. The integrated circuit die 30 may include an interconnect structure 33 over the front side of the semiconductor substrate 32, which may interconnect the devices 31 and the other inactive devices to form an integrated circuit. The interconnect structure 33 may include dielectric layers 33A on the semiconductor substrate 32 and metallization patterns 33B in the dielectric layers 33A. The metallization patterns 33B may be electrically connected to the devices 31 and the other inactive devices.

The integrated circuit die 30 may further include a passivation layer 36 on the interconnect structure 33 and conductive pads 37 in the passivation layer 36. The conductive pads 37 may be physically and electrically connected to the metallization patterns 33B. The passivation layer 36 may comprise silicon nitride, silicon oxide, polyimide, or the like. The conductive pads 37 may comprise copper, nickel, aluminum, the like, or combinations thereof. Conductive connectors 38 may be on the conductive pads 37. The conductive connectors 38 may be solder, such as lead-free solder, or the like.

FIG. 1C illustrates a cross-sectional view of an integrated circuit die 40. The integrated circuit die 40 may be packaged in subsequent processing to form an integrated circuit package. The integrated circuit die 40 may be a memory die, such as dynamic random access memory (DRAM), static random access memory (SRAM), high bandwidth memory (HBM), or the like. The integrated circuit die 40 may include a stack of semiconductor substrates 42. The semiconductor substrates 42 may comprise silicon, germanium, silicon-germanium, or the like. The semiconductor substrates 42 may be bonded together by bonding layers (not shown) between neighboring semiconductor substrates 42. The semiconductor substrates 42 may have front sides (e.g., the sides facing upwards in FIG. 1C), and back sides (e.g., the sides facing downwards in FIG. 1C).

Devices (not shown) may be at the front sides of the semiconductor substrates 42. The devices may include active devices, such as transistors, or the like, and inactive devices, such as capacitors, resistors, or the like. The transistor may comprise a source region, a drain region, a channel region between the source region and the drain region, and a gate structure on the channel region. The devices at the front side of each of the semiconductor substrates 42 may be interconnected by a corresponding interconnect structure (not shown) on the front side of the semiconductor substrate 42. The integrated circuit die 40 may include an interconnect structure 43 over the stack of the semiconductor substrates 42, which may interconnect the devices by through vias 49 in the semiconductor substrates 42 to form an integrated circuit. The interconnect structure 43 may include dielectric layers 43A on the stack of semiconductor substrates 42 and metallization patterns 43B in the dielectric layers 43A. The metallization patterns 43B may be electrically connected to the devices.

The integrated circuit die 40 may further include a passivation layer 46 on the interconnect structure 43 and conductive pads 47 in the passivation layer 46. The conductive pads 47 may be physically and electrically connected to the metallization patterns 43B. The passivation layer 46 may comprise silicon nitride, silicon oxide, polyimide, or the like. The conductive pads 47 may comprise copper, nickel, aluminum, the like, or combinations thereof. Conductive connectors 48 may be on the conductive pads 47. The conductive connectors 48 may be solder, such as lead-free solder, or the like.

FIG. 1D illustrates a cross-sectional view of an integrated circuit die 50. The integrated circuit die 50 may be packaged in subsequent processing to form an integrated circuit package. The integrated circuit die 50 may be an input/output (I/O) die, or the like. The integrated circuit die 50 may also act as a bridge die as described in greater detail below. The integrated circuit die 50 may include a semiconductor substrate 52. The semiconductor substrate 52 may comprise silicon, germanium, silicon-germanium, or the like. The semiconductor substrate 52 may have a front side (e.g., the side facing upwards in FIG. 1D), and a back side (e.g., the side facing downwards in FIG. 1D).

Devices (not shown) may be at the front side of the semiconductor substrate 52. The devices may be inactive devices, such as capacitors, resistors, or the like. The integrated circuit die 50 may be free of active devices, such as transistors or the like. The transistor may comprise a source region, a drain region, a channel region between the source region and the drain region, and a gate structure on the channel region. The integrated circuit die 50 may include an interconnect structure 53 over the front side of the semiconductor substrate 52, which may interconnect the devices to form an integrated circuit. The interconnect structure 53 may include dielectric layers 53A on the semiconductor substrate 52 and metallization patterns 53B in the dielectric layers 53A. The metallization patterns 53B may be electrically connected to the devices.

The integrated circuit die 50 may further include a passivation layer 56 on the interconnect structure 53 and conductive pads 57 in the passivation layer 56. The conductive pads 57 may be physically and electrically connected to the metallization patterns 53B. The passivation layer 56 may comprise silicon nitride, silicon oxide, polyimide, or the like. The conductive pads 57 may comprise copper, nickel, aluminum, the like, or combinations thereof. The integrated circuit die 50 may further include a passivation layer 54 on the back side of the semiconductor substrate 52 and conductive pads 55 in the passivation layer 54. The passivation layer 54 may comprise silicon nitride, silicon oxide, polyimide, or the like. The conductive pads 55 may comprise copper, nickel, aluminum, the like, or combinations thereof. The conductive pads 55 may be electrically connected to the metallization patterns 53B by through vias 59 in the semiconductor substrate 52. Conductive connectors 58 may be on the conductive pads 55. The conductive connectors 58 may be solder, such as lead-free solder, or the like.

FIG. 1E illustrates a cross-sectional view of an integrated circuit die 60. The integrated circuit die 60 may be packaged in subsequent processing to form an integrated circuit package. The integrated circuit die 60 may be a logic die, such as CPU, GPU, SoC, AP, microcontroller, or the like. The integrated circuit die 60 may also act as a bridge die as described in greater detail below. The integrated circuit die 60 may include a semiconductor substrate 62. The semiconductor substrate 62 may comprise silicon, germanium, silicon-germanium, or the like. The semiconductor substrate 62 may have a front side (e.g., the side facing upwards in FIG. 1E), and a back side (e.g., the side facing downwards in FIG. 1E).

Devices 61 may be at the front side of the semiconductor substrate 62. The devices 61 may be active devices, such as transistors, or the like. The transistor may comprise a source region, a drain region, a channel region between the source region and the drain region, and a gate structure on the channel region. Other inactive devices (not shown), such as capacitors, resistors, or the like, may be also at the front side of the semiconductor substrate 62. The integrated circuit die 60 may include an interconnect structure 63 over the semiconductor substrate 62, which may interconnect the devices 61 and the other inactive devices to form an integrated circuit. The interconnect structure 63 may include dielectric layers 63A on the semiconductor substrate 62 and metallization patterns 63B in the dielectric layers 63A. The metallization patterns 63B may be electrically connected to the devices 61 and the other inactive devices.

The integrated circuit die 60 may further include a passivation layer 66 on the interconnect structure 63 and conductive pads 67 in the passivation layer 66. The conductive pads 67 may be physically and electrically connected to the metallization patterns 63B. The passivation layer 66 may comprise silicon nitride, silicon oxide, polyimide, or the like. The conductive pads 67 may comprise copper, nickel, aluminum, the like, or combinations thereof. The integrated circuit die 60 may further include a passivation layer 64 on the back side of the semiconductor substrate 62 and conductive pads 65 in the passivation layer 64. The passivation layer 64 may comprise silicon nitride, silicon oxide, polyimide, or the like. The conductive pads 65 may comprise copper, nickel, aluminum, the like, or combinations thereof. The conductive pads 65 may be electrically connected to the metallization patterns 63B by through vias 69 in the semiconductor substrate 62. Conductive connectors 68 may be on the conductive pads 65. The conductive connectors 68 may be solder, such as lead-free solder, or the like.

FIG. 1F illustrates a cross-sectional view of an integrated circuit die 70. The integrated circuit die 70 may be packaged in subsequent processing to form an integrated circuit package. The integrated circuit die 70 may be a memory die, such as DRAM, SRAM, HBM, or the like. The integrated circuit die 70 may also act as a bridge die as described in greater detail below. The integrated circuit die 70 may include a semiconductor substrate 72. The semiconductor substrate 72 may comprise silicon, germanium, silicon-germanium, or the like. The semiconductor substrates 72 may comprise silicon, germanium, silicon-germanium, or the like. The semiconductor substrates 72 may be bonded together by bonding layers (not shown) between neighboring semiconductor substrates 72. The semiconductor substrates 72 may have front sides (e.g., the sides facing upwards in FIG. 1F), and back sides (e.g., the sides facing downwards in FIG. 1F).

Devices (not shown) may be at the front sides of the semiconductor substrates 72. The devices may include active devices, such as transistors, or the like, and inactive devices, such as capacitors, resistors, or the like. The transistor may comprise a source region, a drain region, a channel region between the source region and the drain region, and a gate structure on the channel region. The devices at the front side of each of the semiconductor substrates 72 may be interconnected by a corresponding interconnect structure (not shown) on the front side of the semiconductor substrate 72. The integrated circuit die 70 may include an interconnect structure 73 over the stack of the semiconductor substrates 72, which may interconnect the devices by through vias 79 in the semiconductor substrates 72 to form an integrated circuit. The interconnect structure 73 may include dielectric layers 73A on the stack of semiconductor substrates 72 and metallization patterns 73B in the dielectric layers 73A. The metallization patterns 73B may be electrically connected to the devices.

The integrated circuit die 70 may further include a passivation layer 76 on the interconnect structure 73 and conductive pads 77 in the passivation layer 76. The conductive pads 77 may be physically and electrically connected to the metallization patterns 73B. The passivation layer 76 may comprise silicon nitride, silicon oxide, polyimide, or the like. The conductive pads 77 may comprise copper, nickel, aluminum, the like, or combinations thereof. The integrated circuit die 70 may further include a passivation layer 74 on the back side of the stack of semiconductor substrate 72 and conductive pads 75 in the passivation layer 74. The passivation layer 74 may comprise silicon nitride, silicon oxide, polyimide, or the like. The conductive pads 75 may comprise copper, nickel, aluminum, the like, or combinations thereof. The conductive pads 75 may be electrically connected to the metallization patterns 73B by the through vias 79 in the semiconductor substrates 72. Conductive connectors 78 may be on the conductive pads 75. The conductive connectors 78 may be solder, such as lead-free solder, or the like.

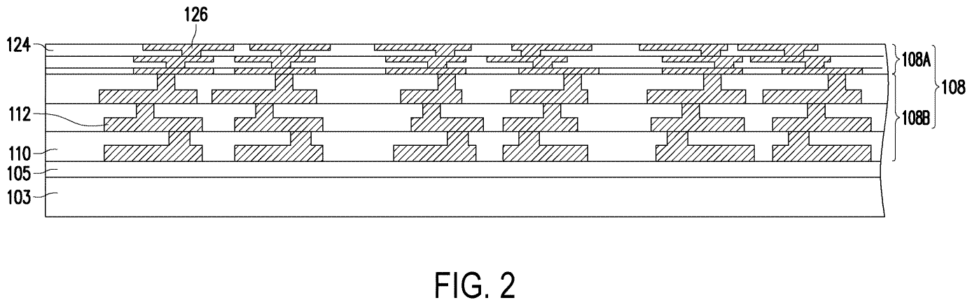

FIGS. 2 through 11B illustrate various views of intermediate steps during a process for forming an integrated circuit package, in accordance with some embodiments. In FIG. 2, a redistribution structure 108 is formed over a carrier substrate 103. The carrier substrate 103 may be a glass carrier substrate, a ceramic carrier substrate, or the like. The carrier substrate 103 may be a wafer, such that the redistribution structure 108 may be a wafer-scale redistribution structure. FIG. 2 shows a portion of the carrier substrate 103 and the redistribution structure 108 for illustrative purposes. An adhesive layer 105 may be between the carrier substrate 103 and the redistribution structure 108. The adhesive layer 105 may be any suitable adhesive, such as epoxy, die attach film (DAF), light-to-heat-conversion (LTHC) material, or the like. The adhesive layer 105 may be removed along with the carrier substrate 103 in a subsequent step.

The redistribution structure 108 may have a fine-featured portion 108A and a coarse-featured portion 108B. The fine-featured portion 108A and the coarse-featured portion 108B may include dielectric layers and metallization patterns in the dielectric layers. The coarse-featured portion 108B may include dielectric layers and metallization patterns of larger sizes than the fine-featured portion 108A. The dielectric layers of the coarse-featured portion 108B may comprise a different material from the dielectric layers of the fine-featured portion 108A. The fine-featured portion 108A and the coarse-featured portion 108B are shown in FIG. 2 to each have three dielectric layers as an example. More or fewer dielectric layers may be formed in the fine-featured portion 108A and the coarse-featured portion 108B. In some embodiments, quantities of the dielectric layers of the fine-featured portion 108A and the coarse-featured portion 108B may be in a range from about 5 to about 9.

The coarse-featured portion 108B may be formed on the carrier substrate 103. The coarse-featured portion 108B may include multiple layers, and each layer may include a dielectric layer 110 and corresponding metallization patterns 112 in the dielectric layer 110. The metallization patterns 112 in the dielectric layer 110 may comprise metal lines and metal vias. The dielectric layers 110 may be formed to a same thickness or different thicknesses. The metal lines of the metallization patterns 112 may be formed to a same thickness or different thicknesses. Thicknesses of the metal lines of the metallization patterns 112 may be in a range from about 5 μm to about 30 μm. The metal vias of the metallization patterns 112 may be formed to a same thickness or different thicknesses. Thicknesses of the metal vias of the metallization patterns 112 may be in a range from about 5 μm to about 30 μm.

As an example of forming the coarse-featured portion 108B, a first layer of the metallization patterns 112 may be first formed on the carrier substrate 103. The first layer of the metallization patterns 112 may comprise metal lines and metal vias. Initially, a seed layer may be formed on the carrier substrate 103. The seed layer may comprise a single metal layer or a composite metal layer comprising a plurality of sub-layers formed of different materials. In some embodiments, the seed layer comprises a titanium layer and a copper layer over the titanium layer. The seed layer may be formed by a suitable deposition method, such as physical vapor deposition (PVD) or the like.

A first photoresist may be formed on the seed layer and patterned. The patterning of the first photoresist may form openings through the first photoresist to expose the seed layer. The openings of the first photoresist may correspond to the metal lines of the first layer of the metallization patterns 112. A conductive material may be then formed in the openings of the first photoresist and on the exposed portions of the seed layer. The conductive material may be a metal, such as copper, titanium, tungsten, aluminum, or the like. The conductive material may be formed by plating, such as electroplating or electroless plating, or the like. Afterwards, the first photoresist and portions of the seed layer on which the conductive material is not formed may be removed by a suitable ashing process and a suitable etching process, respectively. The conductive material and the remaining portions of the seed layer may be referred to as the metal lines of the first layer of the metallization patterns 112.

A second photoresist may be formed on the metal lines and patterned. The patterning may form openings through the second photoresist to expose the metal lines. The openings of the second photoresist may correspond to the metal vias of the first layer of the metallization patterns 112. Then additional conductive material may be formed in the openings of the second photoresist and on the exposed portions of the metal lines formed by plating, such as electroplating or electroless plating, or the like. Afterwards, the second photoresist may be then removed by a suitable ashing process. The additional conductive material may be referred to as the metal vias of the first layer of the metallization patterns 112.

A first layer of the dielectric layers 110 may be then formed around the first layer of the metallization patterns 112. The first layer of the dielectric layers 110 may be formed of a photo-insensitive material, such as molding compound, resin, epoxy, acrylic, polyimide, or the like. The first layer of the dielectric layers 110 may be formed by compression molding, transfer molding, or the like. The photo-insensitive material may be applied in liquid or semi-liquid form initially and subsequently cured. The first layer of the metallization patterns 112 and the first layer of the dielectric layers 110 may be collectively referred to as a first layer of the coarse-featured portion 108B.

Then the process of forming the first layer of the coarse-featured portion 108B may be repeated to form a second layer and a third layer of the coarse-featured portion 108B. The second layer of the coarse-featured portion 108B may comprise a second layer of the metallization patterns 112 and a second layer of the dielectric layers 110. The third layer of the coarse-featured portion 108B may comprise a third layer of the metallization patterns 112 and a third layer of the dielectric layers 110. The metallization patterns 112 in each layer of the coarse-featured portion 108B may be physically and electrically connected to the metallization patterns 112 in neighboring layers of the coarse-featured portion 108B.

The fine-featured portion 108A may be formed on the coarse-featured portion 108B. The fine-featured portion 108A may include multiple layers, and each layer may include a dielectric layer 124 and corresponding metallization patterns 126 in the dielectric layer 124. The metallization patterns 126 in the dielectric layer 124 may comprise metal lines and metal vias. The dielectric layers 124 may be formed to a same thickness or different thicknesses. Thicknesses of the dielectric layers 124 may be smaller than thicknesses of the dielectric layers 110. The metal lines of the metallization patterns 126 may be formed to a same thickness or different thicknesses. Thicknesses of the metal lines of the metallization patterns 126 may be in a range from about 2 μm to about 20 μm, and may be smaller than the thicknesses of the metal lines of the metallization patterns 112. The metal vias of the metallization patterns 126 may be formed to a same thickness or different thicknesses. Thicknesses of the metal vias of the metallization patterns 126 may be in a range from about 2 μm to about 20 μm, and may be smaller than the thicknesses of the metal vias of the metallization patterns 112.

As an example of forming the fine-featured portion 108A, a first layer of the dielectric layers 124 may be first formed on the coarse-featured portion 108B. In some embodiments, the first layer of the dielectric layers 124 are formed of a photo-sensitive material, such as polybenzoxazole (PBO), polyimide, benzocyclobutene (BCB), or the like. In such embodiments, the first layer of the dielectric layers 124 may be formed by a suitable coating process, such as spin coating, lamination, or the like. In some embodiments, the first layer of the dielectric layers 124 are formed of a dielectric material, such as silicon oxide, silicon nitride, or the like. In such embodiments, the first layer of the dielectric layers 124 may be formed by a suitable deposition process, such as chemical vapor deposition (CVD), atomic layer deposition (ALD), or the like. The first layer of the dielectric layers 124 may be then patterned by a suitable lithography process. The patterning may form openings exposing portions of the metallization patterns 112 of the coarse-featured portion 108B.

The first layer of the metallization patterns 126 may be formed in the openings of the first layer of the dielectric layers 124. The first layer of the metallization patterns 126 may comprise metal lines, which may be physically and electrically connected to the exposed portions of the metallization patterns 112. The first layer of the metallization patterns 126 may be formed of same or similar materials and formed by same or similar processes as the first layer of the metallization patterns 112. The first layer of the metallization patterns 126 and the first layer of the dielectric layers 124 may be collectively referred to as a first layer of the fine-featured portion 108A.

Then the process of forming the first layer of the fine-featured portion 108A may be repeated to form a second layer and a third layer of the fine-featured portion 108A. The second layer of the fine-featured portion 108A may comprise a second layer of the metallization patterns 126 and a second layer of the dielectric layers 124. The third layer of the fine-featured portion 108A may comprise a third layer of the metallization patterns 126 and a third layer of the dielectric layers 124. The second layer and the third layers of the metallization patterns 126 may comprise metal lines and metal vias. The metallization patterns 126 in each layer of the fine-featured portion 108A may be physically and electrically connected to the metallization patterns 126 in neighboring layers of the fine-featured portion 108A.

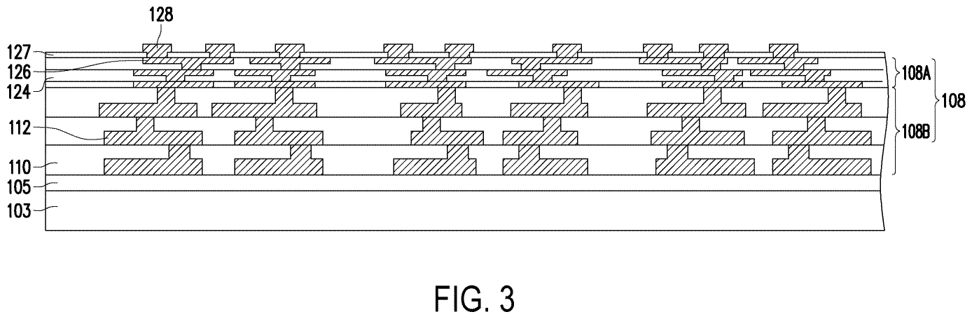

In FIG. 3, a dielectric layer 127 is formed on a top surface of the redistribution structure 108 and under bump metallizations (UBMs) 128 are formed in the dielectric layer 127. The dielectric layer 127 may be formed of a same or similar material and formed by a same or similar process as the first layer of the dielectric layers 124. The UBMs 128 may have line portions on a surface of the dielectric layer 127 and via portions extending through the dielectric layer 127 to physically and electrically connect to the metallization patterns 126 of the redistribution structure 108.

As an example to form the UBMs 128, the dielectric layer 127 may be first patterned. The patterning forms openings exposing portions of the metallization pattern 126 by a suitable photolithography process. A seed layer may be formed on the dielectric layer 127 and in the openings. The seed layer may comprise a single metal layer or a composite metal layer comprising a plurality of sub-layers formed of different materials. In some embodiments, the seed layer comprises a titanium layer and a copper layer over the titanium layer. The seed layer may be formed by a suitable deposition method, such as PVD or the like. A photoresist may be formed on the seed layer and patterned. The patterning forms openings through the photoresist to expose the seed layer. The openings of the photoresist may correspond to the via portions of the UBMs 128. A conductive material may be then formed in the openings of the photoresist and on the exposed portions of the seed layer. The conductive material may be a metal, such as copper, titanium, tungsten, aluminum, or the like. Afterwards, the photoresist and portions of the seed layer on which the conductive material is not formed may be removed by a suitable ashing process and a suitable etching process, respectively. The remaining portions of the conductive material and the seed layer be referred to as the UBMs 128.

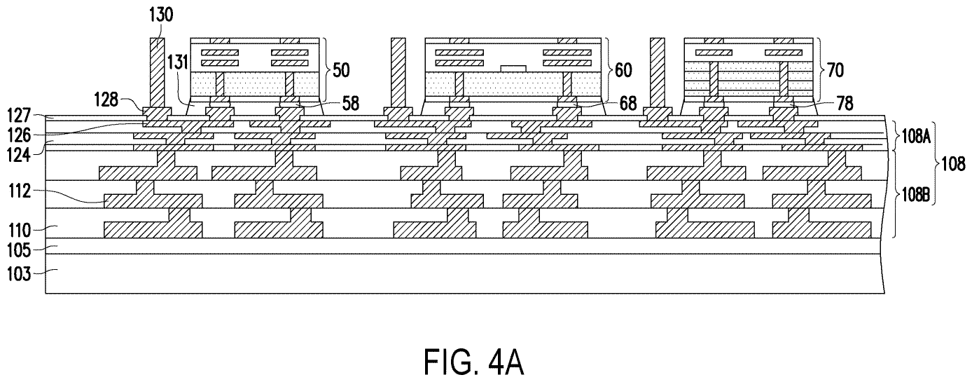

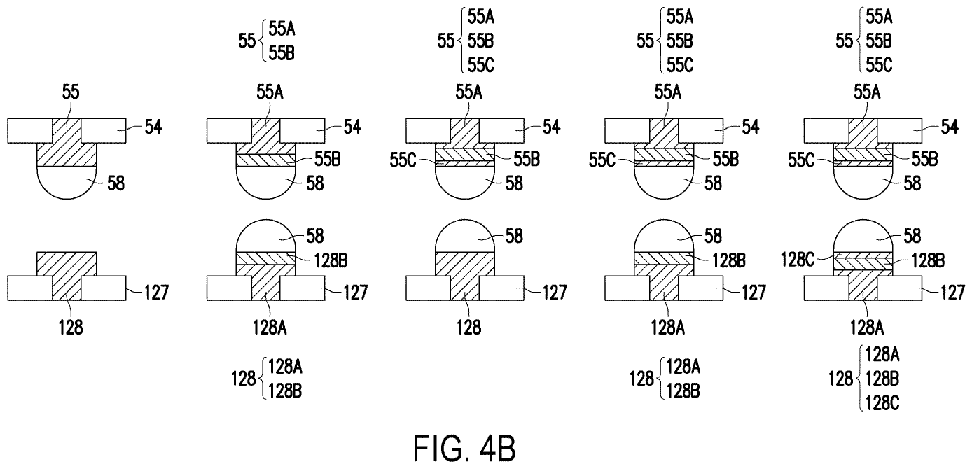

In FIG. 4A, the integrated circuit dies 50, 60, and 70 are bonded to the UBMs 128 and over the redistribution structure 108, and underfills 131 are formed between the integrated circuit dies 50, 60, and 70, and the dielectric layer 127. Further, through vias 130 are formed on the UBMs 128. The integrated circuit dies 50, 60, and 70 may be bonded to the UBMs 128 by the placing the conductive connectors 58, 68, and 78, on the UBMs 128 or on conductive connectors (not shown) previously formed on the UBMs 128, then reflowing the conductive connectors 58, 68, and 78. After the bonding process, the integrated circuit dies 50, 60, and 70 may be electrically connected to the redistribution structure 108. The underfills 131 may be formed of a molding compound, epoxy, or the like. The underfills 131 may be formed by a capillary flow process after the integrated circuit dies 50, 60, and 70 are bonded to the UBMs 128 in liquid or semi-liquid form and then subsequently cured. The through vias 130 may be formed of same or similar materials and formed by same or similar processes as the metallization patterns 112 of the redistribution structure 108. The through vias 130 may be electrically connected to the redistribution structure 108.

FIG. 4B shows various detailed views of a bonding interface between the integrated circuit dies 50 and the UBMs 128 before the bonding process in accordance with some embodiments. Same detailed views may also be applied to a bonding interface between the integrated circuit dies 60 and the UBMs 128, and a bonding interface between the integrated circuit dies 70 and the UBMs 128. In some embodiments, the UBMs 55 and 128 are single-layered structures formed of one conductive material, such as copper, and the conductive connectors 58 may be formed on the UBMs 55, or both the UBMs 55 and the UBMs 128. In some embodiments, the UBMs 55 are multi-layered structures formed of more than one conductive material, such as copper and nickel, and UBMs 128 are single-layered structures formed of one conductive material, such as copper, and the conductive connectors 58 may be formed on the UBMs 55, or both the UBMs 55 and the UBMs 128. For example, the UBMs 55 may comprises copper layers 55A in contact with the passivation layers 54, and nickel layers 55B on the copper layers 55A and in contact with the conductive connectors 58. For example, the UBMs 55 may comprises copper layers 55A in contact with the passivation layers 54, nickel layers 55B on the copper layers 55A, and copper layers 55C on the nickel layers 55B and in contact with the conductive connectors 58.

In some embodiments, the UBMs 55 and 128 are multi-layered structures formed of more than one conductive material, such as copper and nickel, and the conductive connectors 58 may be formed on the UBMs 55 and the UBMs 128. For example, the UBMs 55 may comprises copper layers 55A in contact with the passivation layers 54, and nickel layers 55B on the copper layers 55A and in contact with the conductive connectors 58. For example, the UBMs 128 may comprises copper layers 128A in contact with the dielectric layer 127, and nickel layers 128B on the copper layers 128A and in contact with the conductive connectors 58. For example, the UBMs 55 may comprises copper layers 55A in contact with the passivation layers 54, nickel layers 55B on the copper layers 55A, and copper layers 55C on the nickel layers 55B and in contact with the conductive connectors 58. For example, the UBMs 128 may comprises copper layers 128A in contact with the dielectric layer 127, nickel layers 128B on the copper layers 128A, and copper layers 128C on the nickel layers 128B and in contact with the conductive connectors 58.

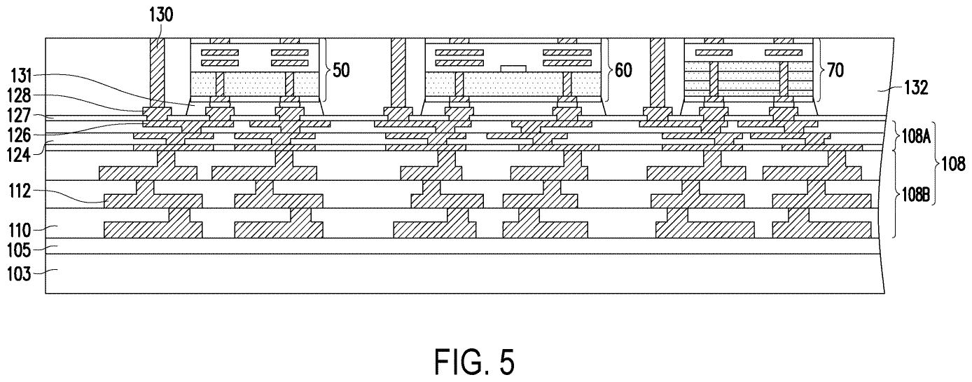

In FIG. 5, an encapsulant 132 is formed around the integrated circuit dies 50, 60, and 70, and the through vias 130. The encapsulant 132 may be a molding compound, epoxy, or the like, and may be applied by compression molding, transfer molding, or the like. The encapsulant 132 may be applied in liquid or semi-liquid form and then subsequently cured. Then a removal process may be performed to remove the excess portion of the encapsulant 132 and expose the integrated circuit dies 50, 60, and 70, and the through vias 130. The removal process may be a chemical-mechanical polish (CMP), an etch-back, combinations therefore, or the like. Top surfaces of the integrated circuit dies 50, 60, and 70, the through vias 130, and the encapsulant 132 may be coplanar (within process variations) after the removal process.

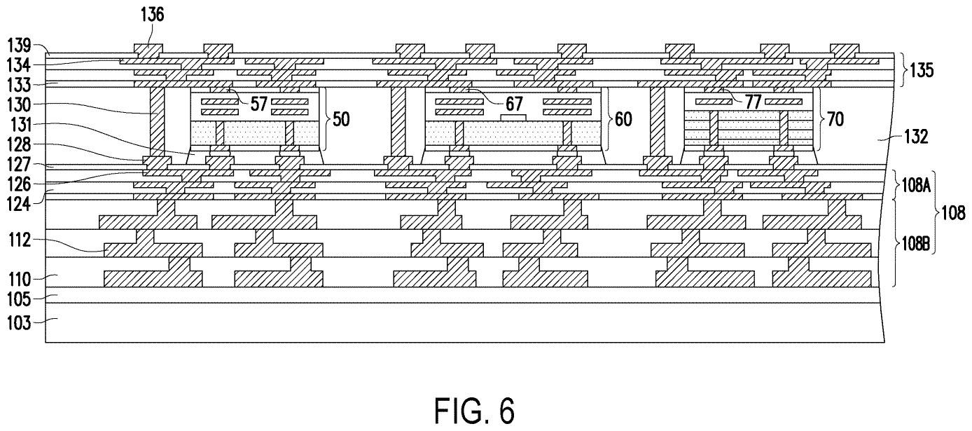

In FIG. 6, a redistribution structure 135 may be formed on the integrated circuit dies 50, 60, and 70, the through vias 130, and the encapsulant 132. Further, a dielectric layer 139 is formed on the redistribution structure 135 and UBMs 136 are formed in the dielectric layer 139. The redistribution structure 135 may be a wafer-scale redistribution structure. The redistribution structure 135 may include multiple layers, and each layer may include a dielectric layer 133 and corresponding metallization patterns 134 in the dielectric layer 133. The metallization patterns 134 in the dielectric layer 133 may comprise metal lines and metal vias. The metallization patterns 134 may be electrically connected to the conductive pads 57 of the integrated circuit dies 50, the conductive pads 67 of the integrated circuit dies 60, the conductive pads 77 of the integrated circuit dies 70, and the through vias 130. The integrated circuit dies 50, 60, and 70 and the through vias 130 may electrically connect the redistribution structure 135 with the redistribution structure 108.

The redistribution structure 135 may be formed of same or similar materials and formed by same or similar processes as the fine-featured portion 108A of the redistribution structure 108. The redistribution structure 135 is shown in FIG. 6 to have three dielectric layers 133 as an example. More or fewer dielectric layers 133 may be formed in the redistribution structure 135. The dielectric layer 139 may be formed of a same or similar material and formed by a same or similar process as the first layer of the dielectric layers 124. The UBMs 136 may have line portions on a surface of the dielectric layer 139 and via portions extending through the dielectric layer 139 to physically and electrically connect to the metallization patterns 134 of the redistribution structure 135. The UBMs 136 may be formed of same or similar materials and formed by same or similar processes as the UBMs 128.

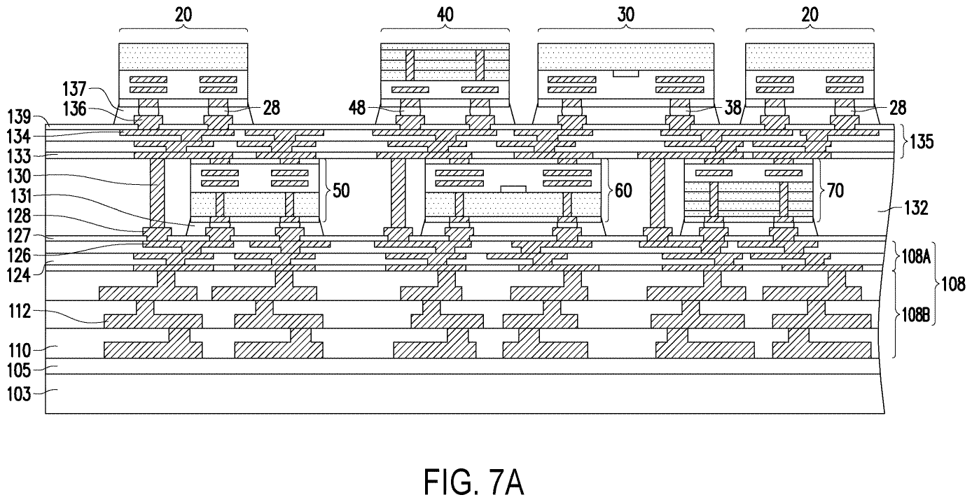

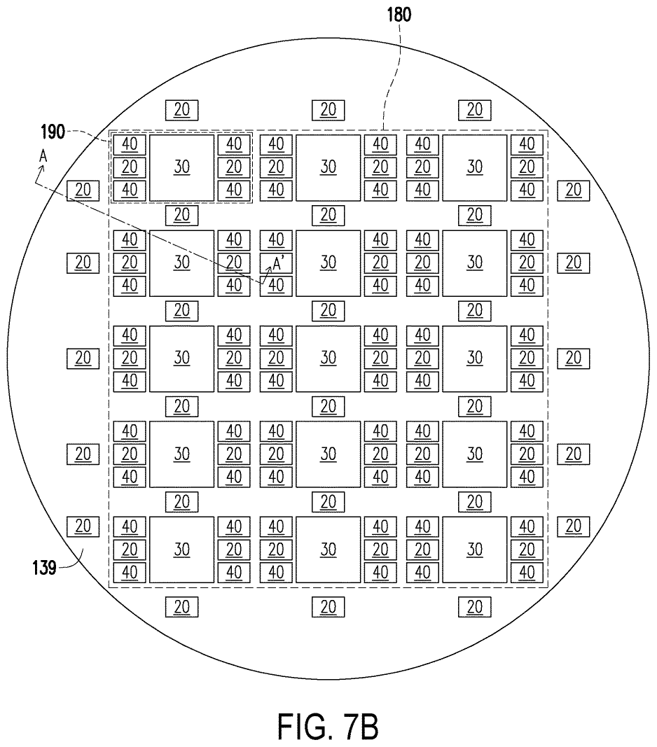

In FIGS. 7A and 7B, the integrated circuit dies 20, 30, and 40 are bonded to the UBMs 136 and over the redistribution structure 135, and underfills 137 are formed between the integrated circuit dies 20, 30, and 40, and the dielectric layer 139. FIG. 7A shows a cross-sectional view and FIG. 7B shows top-down view, and the cross-sectional view of FIG. 7A may be obtained along reference cross-section A-A′ in the top-down view of FIG. 7B. The integrated circuit dies 20, 30, and 40 may be bonded to the UBMs 136 by the placing the conductive connectors 28, 38, and 48, on the UBMs 136 or on conductive connectors (not shown) previously formed on the UBMs 136, then reflowing the conductive connectors 28, 38, and 48. The various detailed views of the bonding interface between the integrated circuit dies 50 and the UBMs 128 before the bonding process described with respect to FIG. 4B may also be applied to a bonding interface between the integrated circuit dies 20 and the UBMs 136, a bonding interface between the integrated circuit dies 30 and the UBMs 136, and a bonding interface between the integrated circuit dies 40 and the UBMs 136. After the bonding process, the integrated circuit dies 20, 30, and 40 may be electrically connected to the redistribution structure 135. The underfills 137 may be formed of a same or similar material and formed by a same or similar process as the underfills 131.

As shown in FIG. 7B, the integrated circuit dies 30 and 40, and some of the integrated circuit dies 20 are located within a computing region 180 over the redistribution structure 135. The integrated circuit dies 20 outside the computing region 180 may be external I/O dies, which may facilitate communication between integrated circuit dies 30 and 40 within the computing region 180, and external devices that may be attached to the subsequently formed integrated circuit package. The integrated circuit dies 20 within the computing region 180 may be internal I/O dies, which may facilitate communication among the integrated circuit dies 30 and 40. The integrated circuit dies 30 and 40, and some of the integrated circuit dies 20 within the computing region 180 may be grouped into die clusters 190, and the die clusters 190 may be arranged in an array comprising horizontal rows and vertical columns.

In the embodiments shown in FIG. 7B, each die cluster 190 comprises an integrated circuit die 30 (e.g., logic die) with one integrated circuit die 20 (e.g., I/O die) and two integrated circuit dies 40 (e.g., memory die) on opposite horizontal sides of the integrated circuit die 30. The integrated circuit die 20 may be between the two integrated circuit dies 40. The integrated circuit dies 20 within the die clusters 190 may be electrically connected to adjacent integrated circuit dies 30 and 40, and facilitate communication between neighboring die clusters 190 in a same horizontal row. Additional integrated circuit dies 20 may be disposed between the integrated circuit dies 30 of the neighboring die clusters 190 in a same vertical column. Such integrated circuit dies 20 may be electrically connected to adjacent integrated circuit dies 30 and 40, and may facilitate communication between neighboring die clusters 190 in the same vertical column.

Further, the integrated circuit dies 50, 60, and 70 underneath the redistribution structure 135 may act as bridge dies (e.g., local interconnects) and may electrically interconnect the integrated circuit dies 20, 30, and 40 (including the external I/O dies), and connect the integrated circuit dies 20, 30, and 40 to the redistribution structure 107. Therefore, the integrated circuit dies 50, 60, and 70 may also facilitate communication among the integrated circuit dies 20, 30, and 40. Due to the integrated circuit dies 20 (e.g., internal I/O dies) within the computing region 180, and the integrated circuit dies 50, 60, and 70 (e.g., bridge dies) underneath the computing region 180, communication among the integrated circuit dies 30 (e.g., logic dies) and the integrated circuit dies 40 (e.g., memory dies) within the computing region 180 may be improved. As a result, the performance of the subsequently formed integrated circuit package may be improved.

The layout of the integrated circuit dies 20, 30, and 40 within the die clusters 190 shown in FIG. 7B is provided as an example, other layouts of the integrated circuit dies 20, 30, and 40 are contemplated. The layout of the die clusters 190 (e.g., three horizontal rows by five vertical columns) shown in FIG. 7B is provided as an example, other layouts of the die clusters 190 (e.g., four horizontal rows by four vertical columns, five horizontal rows by five vertical columns) are contemplated. The layout of the integrated circuit dies 50, 60, and 70 shown in FIG. 7A is provided as an example, other layouts of the integrated circuit dies 50, 60, and 70 are contemplated. In some embodiment, integrated circuit packages comprising the integrated circuit dies 30, such as integrated circuit packages comprising two or more vertically stacked integrated circuit dies 30, may be also bonded over redistribution structure 135. Such integrated circuit packages may replace some or all of the integrated circuit dies 30 bonded over redistribution structure 135.

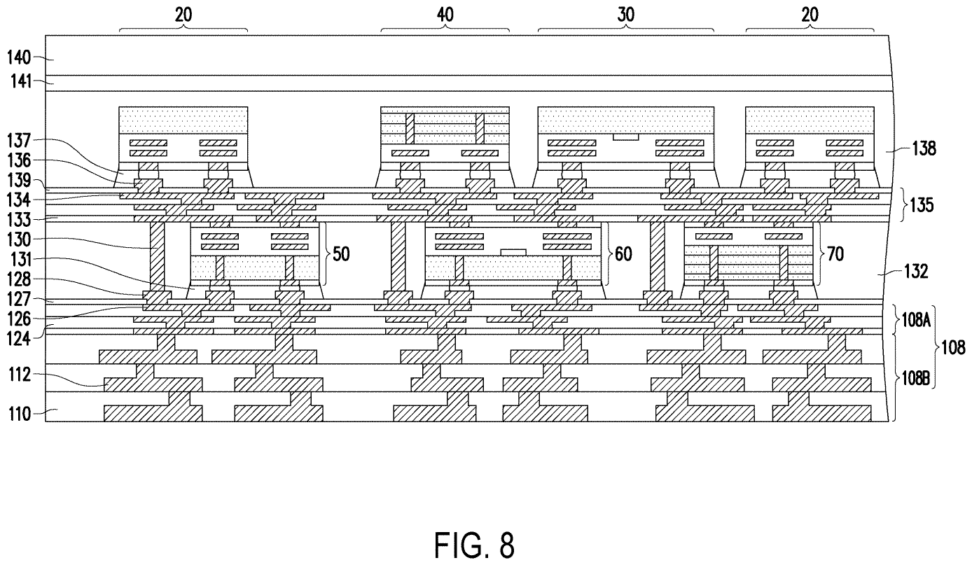

In FIG. 8, an encapsulant 138 is formed around the integrated circuit dies 20, 30, and 40, a carrier substrate 140 is attached to a top surface of the encapsulant 138 by an adhesive layer 141, and the carrier substrate 103 and the adhesive layer 105 are removed. The encapsulant 138 may be formed of a same or similar material and formed by a same or similar process as the encapsulant 132. The carrier substrate 140 may be a glass carrier substrate, a ceramic carrier substrate, or the like. The carrier substrate 140 may be a wafer. The adhesive layer 141 may be any suitable adhesive, such as epoxy, DAF, LTHC material, or the like. The adhesive layer 141 may be removed along with the carrier substrate 140 in a subsequent step. Then, the carrier substrate 103 and the adhesive layer 105 may be removed by projecting a light beam, such as a laser beam, on the adhesive layer 105. As a result of the light exposure, the adhesive layer 105 may be decomposed, and the carrier substrate 103 may be lifted off. Afterwards, a cleaning process, such as a plasma cleaning process, may be performed to clean any reside of the adhesive layer 105 from the redistribution structure 108.

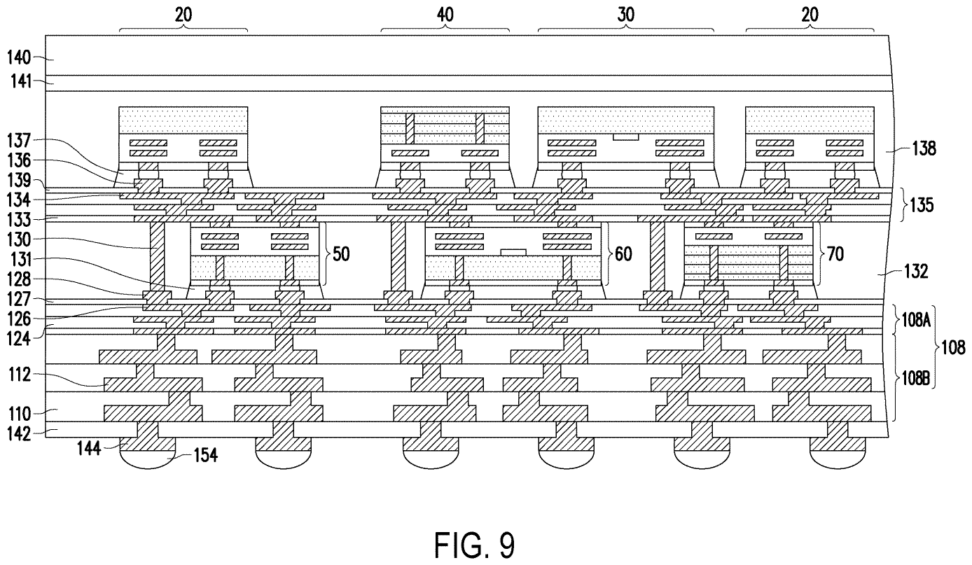

In FIG. 9, a dielectric layer 142 is formed on a bottom surface of the redistribution structure 108, UBMs 144 are formed in the dielectric layer 142, and conductive connectors 154 are formed on the UBMs 144. The dielectric layer 142 may be formed of a same or similar material and formed by a same or similar process as the first layer of the dielectric layers 124. The UBMs 144 may have line portions on a surface of the dielectric layer 142 and via portions extending through the dielectric layer 142 to physically and electrically connect to the metallization patterns 112 of the redistribution structure 108. The UBMs 144 may be formed of same or similar materials and formed by same or similar processes as the UBMs 128. The conductive connectors 154 may be solder, such as lead-free solder, or the like. The UBMs 144 and the corresponding conductive connectors 154 may be used to connect to external devices. Due to the design of the structure shown in FIG. 9, a density of the UBMs 144 and the corresponding conductive connectors 154 may be increased. As a result, the performance of the subsequently formed integrated circuit package may be improved.

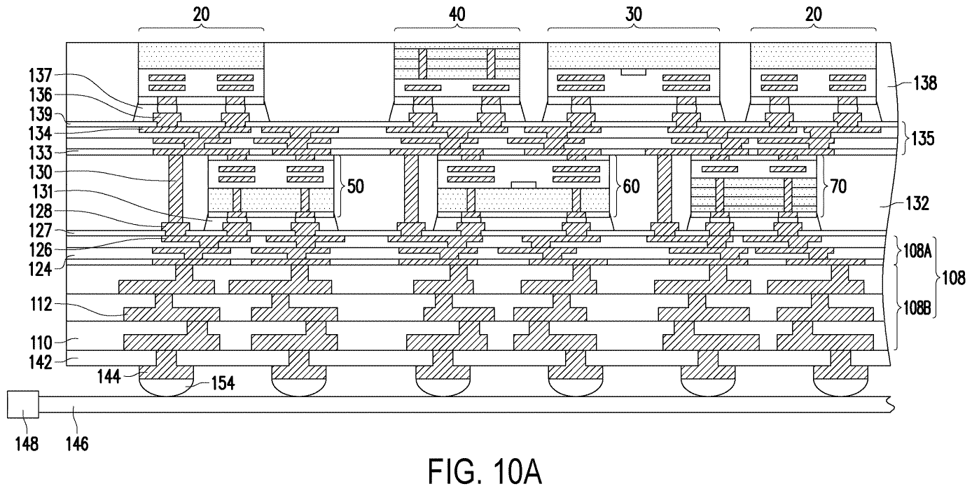

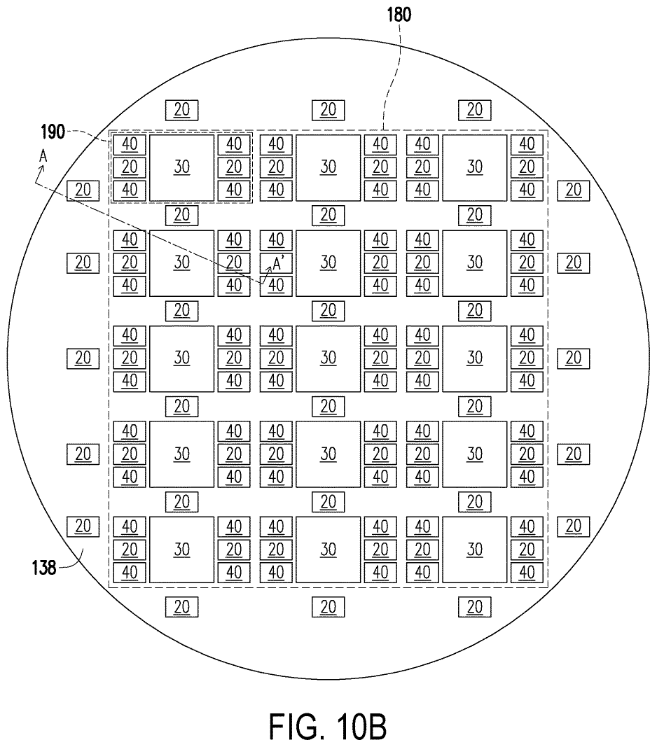

In FIGS. 10A and 10B, the structure shown in FIG. 9 is placed on a tape 146 supported by a frame 148, the carrier substrate 140 and the adhesive layer 141 are removed, and the encapsulant 138 is partially removed to expose surfaces of the integrated circuit dies 20, 30, and 40. FIG. 10A shows a cross-sectional view and FIG. 10B shows top-down view, and the cross-sectional view of FIG. 10A may be obtained along reference cross-section A-A′ in the top-down view of FIG. 10B. The carrier substrate 140 and the adhesive layer 141 may be removed by a same or similar process as the removal of the carrier substrate 103 and the adhesive layer 105. The encapsulant 138 may be partially removed by a process, such as CMP, an etch-back, combinations therefore, or the like. Top surfaces of the integrated circuit dies 20, 30, and 40, and the encapsulant 138 may be coplanar (within process variations) after the removal process.

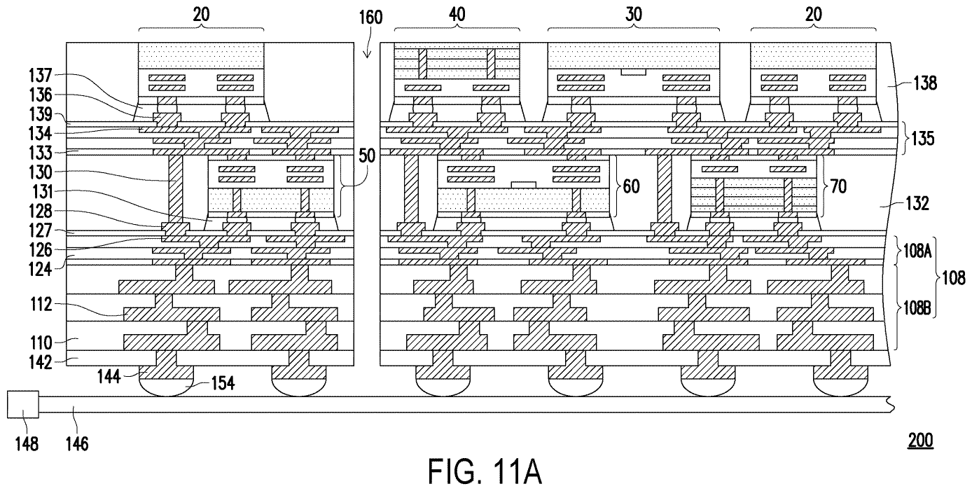

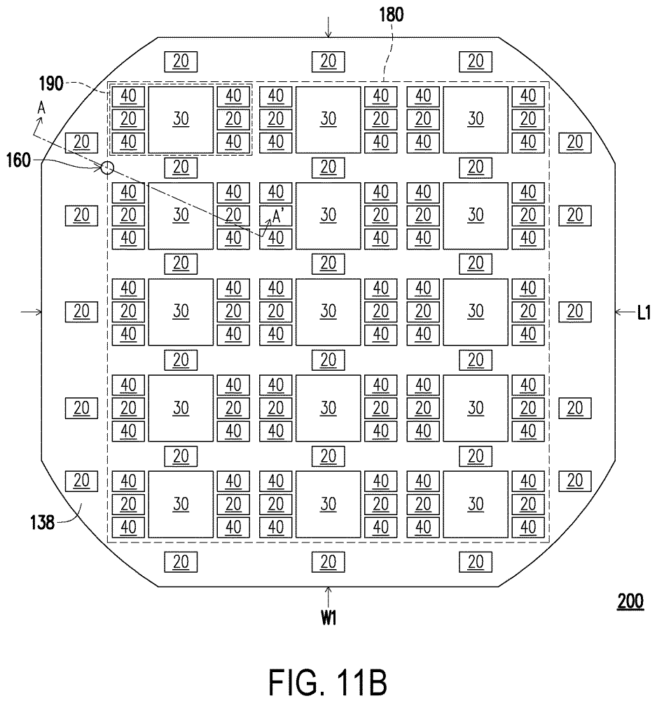

In FIGS. 11A and 11B, openings 160 are formed through the structure shown in FIGS. 10A and 10B and peripheral portions of the structure shown in FIGS. 10A and 10B are truncated. The structure over the tape 146 shown in FIGS. 11A and 11B may be referred to as an integrated circuit package 200. FIG. 11A shows a cross-sectional view and FIG. 11B shows top-down view, and the cross-sectional view of FIG. 11A may be obtained along reference cross-section A-A′ in the top-down view of FIG. 11B. FIGS. 11A and 11B show one opening 160 for illustrative purposes, more than one openings 160 may be formed through the integrated circuit package 200 at selected locations. The openings 160 may extend through the encapsulant 138, the redistribution structure 135, the encapsulant 132, and the redistribution structure 108. The openings 160 may be circular bolt holes, which may be used to secure additional features, such as a thermal module, a mechanical brace, or the like, using bolts in subsequent processes. The openings 160 may be formed by a drilling process, such as laser drilling, mechanical drilling, or the like.

The peripheral portions of the structure shown in FIGS. 10A and 10B may be truncated by a sawing process or the like. As a result, the integrated circuit package 200 may have a truncated circular shape, which may reduce the space occupied by the integrated circuit package 200 in a system. After the peripheral portions are truncated, the integrated circuit package 200 may have a length L1 in a range from about 80 mm to about 300 mm, and a width W1 in a range from about 50 mm to about 300 mm. The redistribution structure 108 and the redistribution structure 135, being parts of the integrated circuit package 200, may also have a same or similar shape with same or similar dimensions. In some embodiments, the peripheral portions of the structure shown in FIGS. 10A and 10B remain and the integrated circuit package 200 has a circular shape.

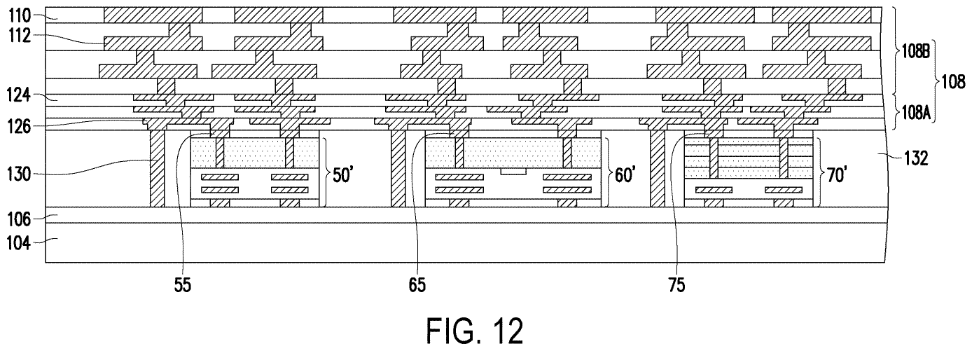

FIGS. 12 through 14 illustrate various views of intermediate steps during a process for forming an integrated circuit package, in accordance with some embodiments. FIG. 12 shows a structure similar to the one shown in FIG. 5 in accordance with some embodiments, wherein like numerals refer to like features formed by like processes. In FIG. 12, integrated circuit dies 50′, 60′, and 70′ may be attached to a carrier substrate 104 by an adhesive layer 106, and the through vias 130 may be formed over the carrier substrate 104 and beside the integrated circuit dies 50′, 60′, and 70′. The encapsulant 132 may be formed around the integrated circuit dies 50′, 60′, and 70′, and the through vias 130. The redistribution structure 108 may be formed on the integrated circuit dies 50′, 60′, and 70′, the through vias 130, and the encapsulant 132.

The carrier substrate 104 may be similar to the carrier substrate 103, and the adhesive layer 106 may be similar to the adhesive layer 105. The integrated circuit dies 50′, 60′, and 70′ may be similar to the integrated circuit dies 50, 60, and 70. The integrated circuit dies 50′, 60′, and 70′ may be without the conductive connectors 58, 68, and 78, respectively. As a result, the conductive pads 55, 65, and 75 of the integrated circuit dies 50′, 60′, and 70′, respectively, may be physically and electrically connected to the metallization patterns 126 of the redistribution structure 108, and the integrated circuit dies 50′, 60′, and 70′ may be in physical contact with the fine-featured portion 108A of the redistribution structure 108. The through vias 130 may be physically and electrically connected to the metallization patterns 126 of the redistribution structure 108.

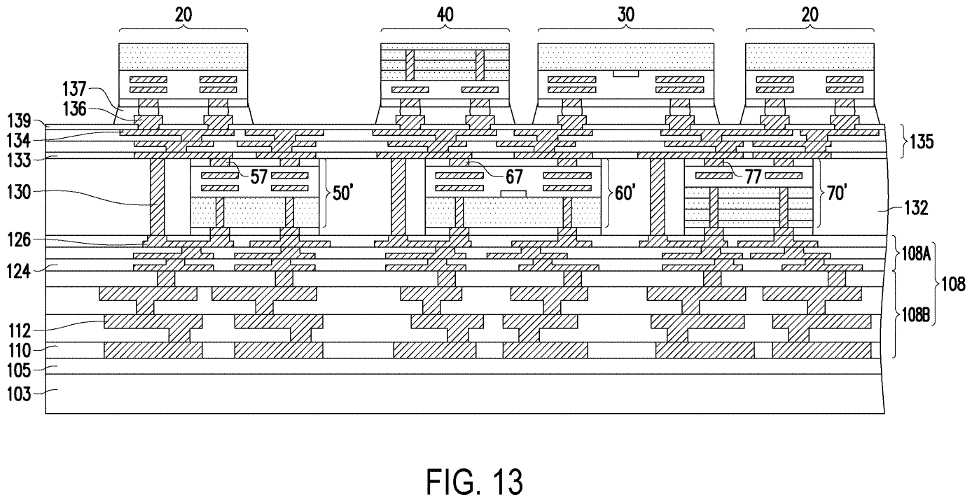

In FIG. 13, the carrier substrate 104 and the adhesive layer 106 are removed and the carrier substrate 103 is attached to the bottom surface of the redistribution structure 108 by the adhesive layer 105. Then the redistribution structure 135 is formed on the integrated circuit dies 50′, 60′, and 70′, the through vias 130, and the encapsulant 132, and the dielectric layer 139 and the UBMs 136 are formed on the redistribution structure 135 by same or similar processes described above with respect to FIG. 6. Next, the integrated circuit dies 20, 30, and 40 are bonded to the UBMs 136, and underfills 137 are formed between the integrated circuit dies 20, 30, and 40, and the dielectric layer 139 by same or similar processes described above with respect to FIG. 7.

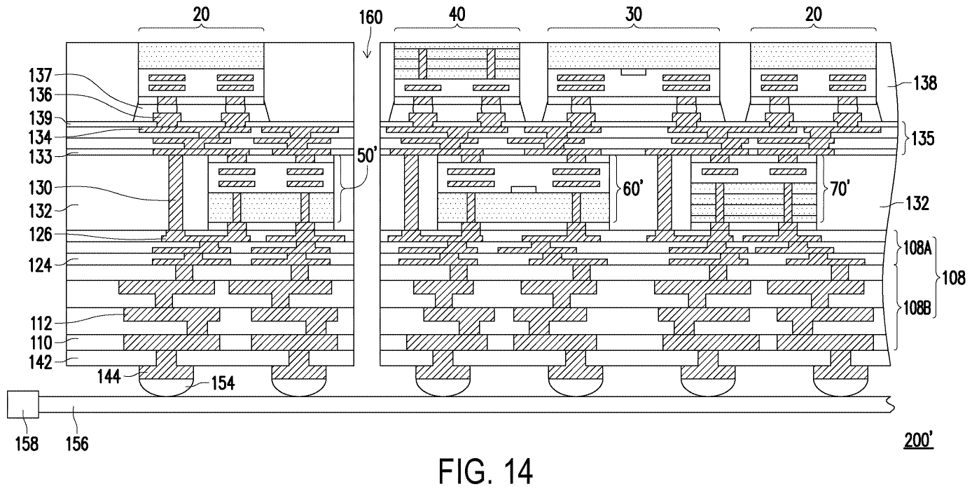

In FIG. 14, the encapsulant 138 is formed around the integrated circuit dies 20, 30, and 40, and the carrier substrate 103 and the adhesive layer 105 are removed by same or similar processes described above with respect to FIG. 8. Then, the dielectric layer 142 and the UBMs 144 are formed on the bottom surface of the redistribution structure 108, and the conductive connectors 154 are formed on the UBMs 144 by same or similar processes described above with respect to FIG. 9. Next, the resulting wafer structure is placed on the tape 146, openings 160 are formed through the wafer structure, and peripheral portions of the wafer structure are truncated by same or similar processes described above with respect to FIGS. 10A through 11B. The structure over the tape 146 shown in FIG. 14 may be referred to as an integrated circuit package 200′.

Embodiments described above may achieve certain advantages. By placing integrated circuit dies 20 within the computing region 180, and the integrated circuit dies 50, 60, and 70 underneath the computing region 180, the communication among the integrated circuit dies 30 and the integrated circuit dies 40 within the computing region 180 may be improved. As a result, the performance of the integrated circuit packages 200 and 200′ may be improved.

In an embodiment, an integrated circuit package includes a first redistribution structure; a first bridge die over the first redistribution structure; a first encapsulant around the first bridge die; a second redistribution structure over the first bridge die and the first encapsulant, wherein the first bridge die electrically connects the first redistribution structure to the second redistribution structure; a first logic die, a second logic die, and a first input/output (I/O) die over the second redistribution structure, wherein the first I/O die is between the first logic die and the second logic die in a top-down view, and wherein the first I/O die electrically connects the first logic die to the second logic die; and a second encapsulant around the first logic die, the second logic die, and the first I/O die. In an embodiment, the integrated circuit package further includes a second I/O die over the second redistribution structure, wherein the second encapsulant is around the second I/O die, wherein the second I/O die is between an edge of the second encapsulant and the first logic die in the top-down view. In an embodiment, the first I/O die is an internal I/O die configured to communicatively couple the first logic die and the second logic die, and wherein the second I/O die is an external I/O die configured to communicatively couple the first logic die and an external device. In an embodiment, the first bridge die includes a transistor, wherein the transistor has a source region, a drain region, a channel region between the source region and the drain region, and a gate structure on the channel region. In an embodiment, the integrated circuit package further includes a bolt hole extending through the first redistribution structure, the first encapsulant, the second redistribution structure, and the second encapsulant. In an embodiment, first redistribution structure and the second redistribution structure are wafer-scale redistribution structures. In an embodiment, the integrated circuit package further includes a first memory die over the second redistribution structure, wherein the second encapsulant is around the first memory die. In an embodiment, first redistribution structure includes a first portion and a second portion, wherein the first portion is between the first bridge die and the second portion, and wherein metal lines in the second portion are thicker than metal lines in the first portion.

In an embodiment, a method includes forming a first redistribution structure; placing a first bridge die over the first redistribution structure, wherein the first bridge die is electrically connected to the first redistribution structure; forming a second redistribution structure over the first bridge die, wherein the first bridge die is electrically connected to the second redistribution structure; bonding a first logic die, a second logic die, a first input/output (I/O) die, and a second input/output (I/O) die over the second redistribution structure, wherein the first I/O die is between the first logic die and the second logic die in a top-down view; and forming an opening through the first redistribution structure and the second redistribution structure. In an embodiment, the opening is formed by laser drilling. In an embodiment, the opening may be between the second I/O die and the first logic die in the top-down view. In an embodiment, the method further includes bonding a first memory die over the second redistribution structure, wherein the first memory die is between the second I/O die and the first logic die in the top-down view. In an embodiment, the first redistribution structure includes a fine-featured portion and a coarse-featured portion, and wherein the fine-featured portion includes thinner dielectric layers and metal lines than the coarse-featured portion. In an embodiment, the method further includes forming a first conductive via beside the first bridge die, wherein the first conductive via is electrically connected to the first redistribution structure and the second redistribution structure.

In an embodiment, a method includes forming a first redistribution structure; connecting a first bridge die to the first redistribution structure; forming a second redistribution structure over the first bridge die, wherein the first bridge die electrically connects the first redistribution structure to the second redistribution structure; connecting a first cluster of integrated circuit dies to a the second redistribution structure, wherein the first cluster of integrated circuit dies includes a first logic die, a first memory die, and a first input/output (I/O) die; and forming a screw hole through the first redistribution structure and the second redistribution structure. In an embodiment, the first cluster of integrated circuit dies further includes a second memory die and a second I/O die, wherein the first memory die and the first I/O die are along a first side of the first logic die in a top-down view, and wherein the second memory die and the second I/O die are along a second side of the first logic die opposite the first side in the top-down view. In an embodiment, the first cluster of integrated circuit dies further includes a third memory die along the first side of the first logic die in the top-down view, and wherein the first I/O die is between the first memory die and the third memory die. In an embodiment, the method further includes connecting a second cluster of integrated circuit dies to the second redistribution structure, wherein the second cluster of integrated circuit dies includes a second logic die, a second memory die, and a second I/O die, and wherein the second memory die and the second I/O die are between the first logic die and the second logic die in a top-down view. In an embodiment, the method further includes connecting a second cluster of integrated circuit dies to the second redistribution structure, wherein the second cluster of integrated circuit dies includes a second logic die, a second memory die, and a second I/O die; and connecting a third I/O die to the second redistribution structure, wherein the third I/O die is between the first cluster of integrated circuit dies and the second cluster of integrated circuit dies. In an embodiment, the first redistribution structure includes a first portion and a second portion, wherein the first portion is between the first bridge die and the second portion, wherein the first portion includes a first plurality of dielectric layers of a first material, wherein the second portion includes a second plurality of dielectric layers of a second material, and wherein the first material is different from the second material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit package comprising:
a wafer-scale redistribution structure comprising a fine-featured portion and a coarse-featured portion, wherein the fine-featured portion comprises first dielectric layers and first metallization patterns in the first dielectric layers, wherein the coarse-featured portion comprises second dielectric layers and second metallization patterns in the second dielectric layers, wherein the first dielectric layers comprise a first material, wherein the second dielectric layers comprise a second material different from the first material, and wherein metal lines of the first metallization patterns are thinner than metal lines of the second metallization patterns;
a bridge die over the wafer-scale redistribution structure, wherein the bridge die is electrically connected to the wafer-scale redistribution structure; and
a logic die electrically connected to the bridge die.

2. The integrated circuit package of claim 1, wherein the metal lines of the first metallization patterns have thicknesses in a range from 2 μm to 20 μm, and wherein the metal lines of the second metallization patterns have thicknesses in a range from 5 μm to 30 μm.

3. The integrated circuit package of claim 1, wherein the first material is a photo-sensitive material, and wherein the second material is a photo-insensitive material.

4. The integrated circuit package of claim 1, wherein the first dielectric layers are thinner than the second dielectric layers.

5. The integrated circuit package of claim 1, wherein the fine-featured portion is between the coarse-featured portion and the bridge die.

6. The integrated circuit package of claim 1, wherein the bridge die comprises a semiconductor substrate and a through via extending through the semiconductor substrate.

7. The integrated circuit package of claim 1, further comprising a second redistribution structure over the bridge die, wherein the bridge die electrically connects the wafer-scale redistribution structure to the second redistribution structure, and wherein the logic die is over the second redistribution structure.

8. A method comprising:
forming a first redistribution structure;
bonding a bridge die over the first redistribution structure, wherein the bridge die comprises a semiconductor substrate and a through via extending through the semiconductor substrate, wherein the bridge die is electrically connected to the first redistribution structure through the through via in the semiconductor substrate;
forming an encapsulant around the bridge die; and
forming a second redistribution structure over the bridge die and the encapsulant, wherein the bridge die electrically connects the first redistribution structure to the second redistribution structure.

9. The method of claim 8, further comprising forming a conductive via beside the bridge die and through the encapsulant, wherein the conductive via is electrically connected to the first redistribution structure and the second redistribution structure.

10. The method of claim 8, further comprising bonding a logic die, a memory die, and an input/output (I/O) die over the second redistribution structure.

11. The method of claim 10, wherein the I/O die is between the logic die and the memory die in a top-down view, and wherein the bridge die facilitates communication among the logic die and the memory die.

12. The method of claim 8, wherein the bridge die is an input/output die.

13. The method of claim 8, wherein the first redistribution structure comprises a fine-featured portion and a coarse-featured portion, and wherein the fine-featured portion comprises thinner metal lines than the coarse-featured portion.

14. The method of claim 8, further comprising forming an opening through the first redistribution structure and the second redistribution structure, wherein the opening is a bolt hole.

15. A method comprising:
forming a wafer-scale redistribution structure;
bonding integrated circuit dies over the wafer-scale redistribution structure, wherein the integrated circuit dies comprise a logic die and a memory die;
forming an encapsulant around the integrated circuit dies;
forming an opening through the wafer-scale redistribution structure and the encapsulant, wherein the opening is a bolt hole; and
truncating peripheral portions of the wafer-scale redistribution structure and the encapsulant to form an integrated circuit package having a truncated circular shape.

16. The method of claim 15, wherein the opening is formed by laser drilling.

17. The method of claim 15, wherein the bolt hole is configured to secure a thermal module or a mechanical brace.

18. The method of claim 15, wherein the integrated circuit dies further comprise an input/output (I/O) die, and wherein the I/O die is between the logic die and the memory die in a top-down view.

19. The method of claim 15, further comprising grouping the integrated circuit dies into die clusters arranged in an array comprising horizontal rows and vertical columns.

20. The method of claim 15, wherein the integrated circuit package has a length in a range from 80 mm to 300 mm and a width in a range from 50 mm to 300 mm.
